(19) United States
(12) Patent Application Publication
(10) Pub. No.: US 2026/0297422 A1
(43) Pub. Date: Oct. 1, 2026

(54) QUANTUM DOT COMPOSITION, RESIN COMPOSITION, AND WAVELENGTH CONVERSION MATERIAL

(71) Applicant: SHIN-ETSU CHEMICAL CO., LTD., Tokyo (JP)

(72) Inventors: Kazuya TOBISHIMA, Annaka-shi (JP); Yoshihiro NOJIMA, Annaka-shi (JP); Shinji AOKI, Annaka-shi (JP)

(73) Assignee: SHIN-ETSU CHEMICAL CO., LTD., Tokyo (JP)

(21) Appl. No.: 19/480,115

(22) PCT Filed: May 8, 2024
(86) PCT No.: PCT/JP2024/017020

§ 371 Date: Oct. 30, 2025

(30) Foreign Application Priority Data
May 18, 2023 (JP) 2023-082450

(51) Int. Cl. C09K 11/02; C09K 11/70; C09K 11/88; C09K 113/00; H10H 20/851

(52) U.S. Cl. CPC C09K 11/025; C09K 11/70; C09K 11/88; C09K 2113/00; H10H 20/8512

(57) ABSTRACT

A quantum dot composition including a quantum dot that emits fluorescence by excitation light, the quantum dot including a semiconductor nanoparticle core and a semiconductor nanoparticle shell that do not contain Cd and Pb, wherein a surface of the quantum dot is coated with a metal oxide, and the surface of the quantum dot or a surface of the metal oxide is modified with a phosphonic acid derivative. This provides a quantum dot composition that prevents reduction in the fluorescence emission efficiency despite using a low-toxicity quantum dot.

### TECHNICAL FIELD

The present invention relates to a quantum dot composition, a resin composition, and a wavelength conversion material.

### BACKGROUND ART

In quantum dots composed of semiconductor particles with nanometer-sized particle diameters, excitons generated by light absorption are confined in nanometer-sized spaces, resulting in discrete energy levels of the semiconductor nanoparticles. The band gap thereof depends on the particle diameter. Accordingly, the fluorescence emission of the quantum dots is highly efficient, and the emission spectrum thereof is sharpened. In addition, the property of the band gap changing with particle diameter leads to a feature of being able to control the emission wavelength, and the application as wavelength conversion materials in solid-state lighting or displays is expected (Patent Document 1).

Examples of the quantum dots exhibiting excellent fluorescence emission properties include quantum dots containing Cd or Pb. However, Cd and Pb are highly toxic to the human body and the environment, and thus restrictions on the use thereof are being considered around the world, including the European Union's RoHS Directive. As a result, quantum dots that do not contain these toxic elements are being investigated.

In addition, as a method for mounting quantum dots as a wavelength conversion material, a method is proposed in which quantum dots are dispersed in a resin material and a resin composition containing the quantum dots is laminated with a transparent film, thereby incorporating the resulting wavelength conversion film into a backlight unit (Patent Document 2).

However, since quantum dots have a small particle diameter on the order of nanometers, they have a large specific surface area and a high surface energy, and are surface-active, and therefore tend to become unstable. As a result, surface defects are easily formed on the surface of the quantum dots due to dangling bonds, oxidation reactions or the like, which cause deterioration of the fluorescence emission properties. Currently available quantum dots have these stability problems, and are known to cause deterioration of the emission properties due to heat, humidity, photoexcitation, and the like.

To prevent the above-described deterioration, organic ligands, referred to as ligands, are coordinated to the surfaces of the synthesized quantum dots. The coordination of these ligands not only improves dispersibility in solvents and resins, but also causes defects to be passivated, thereby allowing the reduction in fluorescence emission efficiency to be prevented.

However, when an appropriate ligand is not selected for the surface of the quantum dots, external influences such as heat and light exposure cause the ligand to detach from the surface of the quantum dots, resulting in reduction in fluorescence emission efficiency.

Changes in the fluorescence emission efficiency of quantum dots over time lead to defects such as color unevenness, emission unevenness, and missing dots for use in displays. The stability of quantum dots is therefore an important issue.

### CITATION LIST

### Patent Literature

Patent Document 1: JP 2012-022028 A
Patent Document 2: JP 2013-544018 A
Patent Document 3: JP 2019-215516 A
Patent Document 4: JP 5900720 B
Patent Document 5: JP 2018-109141 A

### SUMMARY OF INVENTION

### Technical Problem

In response to these problems, methods have been investigated, such as allowing quantum dots to be supported on inorganic oxides (Patent Document 3), and using a gas barrier film with low oxygen and moisture permeability to improve the stability of quantum dots (Patent Document 4).

In the method of allowing quantum dots to be supported on oxides, reduction in fluorescence emission efficiency can be inhibited by preventing direct contact of oxygen and water with the surface of the quantum dots and suppressing oxidation reactions.

However, in a method such as the common sol-gel method, in which metal oxide precursors are reacted in a liquid phase at low temperatures, numerous hydroxy groups remain on the surface of the oxide after the reaction. These hydroxy groups on the surface form hydrogen bonds with water molecules in the air, forming a nano-scale thin layer of adsorbed water, known as a hydration layer, on the surface of the oxide.

It is difficult to completely remove the hydroxy groups on the surface of the oxide by heating, and when a composition in which quantum dots are supported on an oxide is used as a wavelength conversion material, it is used in an environment exposed to light and heat for long periods of time, and thus the adsorbed water that penetrates from the surface of the oxide to the interior causes gradual progress of an oxidation reaction on the surface of the quantum dots, resulting in reduction in the fluorescence emission efficiency.

In addition, stabilization using a barrier film poses the problem of progressive deterioration due to the diffusion of oxygen and water vapor from edges of the film.

Further, for mobile applications such as tablets and smartphones, thinner wavelength conversion films are required, but barrier films generally have a thickness of approximately 20 to 200 μm, and in order to protect both sides of the film, the thickness must be increased by at least 40 μm or more, which places a limit on how thin the wavelength conversion film can be.

Further, a method has been proposed in which quantum dots are used as color filters, rather than as wavelength conversion films, to directly convert blue excitation light into green and red (Patent Document 5). When quantum dots are used as color filters, barrier films and the like cannot be used as in the above-described wavelength conversion films, and reduction in fluorescence emission efficiency of the quantum dot due to curing of the quantum dot composition, subsequent manufacturing processes, and prolonged use becomes a major issue.

Thus, quantum dots that do not contain toxic elements have been investigated, but reduction in fluorescence emission efficiency remains as a problem.

The present invention has been made to solve the above problem, and an object thereof is to provide a quantum dot composition, a resin composition including the quantum dot composition, and a wavelength conversion material that prevents reduction in fluorescence emission efficiency, despite using low-toxicity quantum dots.

### Solution to Problem

The present invention has been made to achieve the above-described object, and provides a quantum dot composition comprising a quantum dot that emits fluorescence by excitation light, the quantum dot comprising a semiconductor nanoparticle core and a semiconductor nanoparticle shell that do not contain Cd and Pb, wherein a surface of the quantum dot is coated with a metal oxide, and the surface of the quantum dot or a surface of the metal oxide is modified with a phosphonic acid derivative.

Such a quantum dot composition prevents reduction in fluorescence emission efficiency when composed of quantum dots with low toxicity.

In this case, it is preferable that the quantum dot comprise the semiconductor nanoparticle core and a single or a plurality of the semiconductor nanoparticle shells covering the semiconductor nanoparticle core.

Such a quantum dot composition is preferable in terms of fluorescence emission properties and stability.

In this case, it is preferable that the semiconductor nanoparticle core comprise one or more selected from ZnS, ZnSe, ZnTe, AlN, AlP, AlAs, AlSb, GaN, GaP, GaAs, GaSb, InN, InP, InAs, InSb, AgGaS₂, AgInS₂, AgGaSe₂, AgInSe₂, CuGaS₂, CuGaSe₂, CuInS₂, CuInSe₂, ZnSiP₂, and ZnGeP₂, or a mixed crystal thereof.

Such a quantum dot composition is preferable in terms of fluorescence emission properties and stability.

In this case, it is preferable that a surface of the semiconductor nanoparticle core be passivated with one or more compounds selected from GaCl₃, GaI₃, GaBr₃, ZnCl₂, ZnBr₂, ZnI₂, InCl₃, InBr₃, InI₃, AgCl, AgBr, AgI, KCl, KBr, KI, NaCl, NaBr, NaI, MgCl₂, MgBr₂, MgI₂, CaCl₂), CaBr₂, CaI₂, MnCl₂, MnBr₂, MnI₂, FeCl₂, FeBr₂, FeI₂, CuCl₂, CuBr₂, CuI₂, ZrCl₄, ZrBr₄, ZrI₄, GeCl₄, GeBr₄, and GeI₄.

Such a quantum dot composition is preferable in terms of fluorescence emission properties and stability.

In this case, it is preferable that the semiconductor nanoparticle shell comprise one or more selected from ZnS, ZnSe, ZnTe, AlN, AlP, AlAs, AlSb, GaN, GaP, GaAs, GaSb, InN, InP, InAs, and InSb, or a mixed crystal thereof.

Such a quantum dot composition is preferable in terms of improved fluorescence emission efficiency and stability.

In this case, it is preferable that the metal oxide be at least one compound selected from TiO₂, ZnO, Al₂O₃, SiO₂, ZrO₂, Fe₂O₃, MgO, Y₂O₃, HfO₂, CeO₂, In₂O₃, SnO₂, WO₃, CrO₃, Ta₂O₃, BaTiO₃, V₂O₅, NiO, NbO, Cu₂O, CuO, and MoO₃.

Such a quantum dot composition is preferable in terms of improved fluorescence emission efficiency and stability.

In this case, it is preferable that the phosphonic acid derivative be represented by the following formula (I):

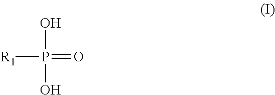

wherein R₁ is a monovalent organic group having one or more carbon atoms.

Such a quantum dot composition prevents reduction in fluorescence emission efficiency and improves stability.

In this case, it is preferable that the phosphonic acid derivative be one or more selected from 3-phenyl-2-propynylphosphonic acid, tenofovir, 2-phosphonobutane-1,2,4-tricarboxylic acid, 4-phosphonobenzoic acid, vinylphosphonic acid, n-octylphosphonic acid, (3-bromopropyl)phosphonic acid, (4-bromobutyl)phosphonic acid, (2-bromoethyl)phosphonic acid, (4-bromophenyl)phosphonic acid, 3-phosphonopropionic acid, (4-hydroxyphenyl)phosphonic acid, hexylphosphonic acid, 4-phosphonobutyric acid, propylphosphonic acid, (4-aminobenzyl)phosphonic acid, (4-aminophenyl)phosphonic acid, 3-phosphonobenzoic acid, methylphosphonic acid, nonylphosphonic acid, benzhydrylphosphonic acid, octadecylphosphonic acid, (aminomethyl)phosphonic acid, (2-phenylethyl)phosphonic acid, ethylphosphonic acid, butylphosphonic acid, decylphosphonic acid, dodecylphosphonic acid, (2-chloroethyl)phosphonic acid, 4-methoxyphenylphosphonic acid, hexadecylphosphonic acid, (4-hydroxybenzyl)phosphonic acid, phenylphosphonic acid, (1H,1H,2H,2H-heptadecafluorodecyl)phosphonic acid, tetradecylphosphonic acid, (1-aminoethyl)phosphonic acid, undecylphosphonic acid, heptylphosphonic acid, 10-carboxydecylphosphonic acid, 11-aminoundecylphosphonic acid hydrobromide, 11-hydroxyundecylphosphonic acid, 1H,1H,2H,2H-perfluoro-n-hexylphosphonic acid, 1H,1H,2H,2H-perfluorooctylphosphonic acid, 1H,1H,2H,2H-perfluoro-n-decylphosphonic acid, 11-{2-[2-(2-methoxyethoxy)ethoxy]ethoxy}undecylphosphonic acid, 12-mercaptodecylphosphonic acid, and [11-(acryloyloxy)undecyl]phosphonic acid.

Such phosphonic acid derivatives can be used in the quantum dot composition of the present invention, preventing reduction in fluorescence emission efficiency and improving stability.

In this case, the phosphonic acid derivative is preferably represented by the following formula (II):

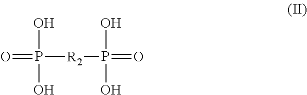

wherein R₂ is a divalent organic group having one or more carbon atoms.

Such a quantum dot composition prevents reduction in fluorescence emission efficiency and improves stability.

In this case, it is preferable that the phosphonic acid derivative be one or more selected from m-xylylenediphosphonic acid, o-xylylenediphosphonic acid, methylenediphosphonic acid, alendronic acid, 1,4-butylenediphosphonic acid, glycine-N,N-bis(methylenephosphonic acid), p-xylylenediphosphonic acid, zoledronic acid, 1,3-propylenediphosphonic acid, 1,5-pentylenediphosphonic acid, 1,4-phenylenediphosphonic acid, 1,2-ethylenediphosphonic acid, 1,6-hexylenediphosphonic acid, minodronate, and 1-hydroxyethane-1,1-diphosphonic acid.

Such phosphonic acid derivatives can be used in the quantum dot composition of the present invention.

In this case, the phosphonic acid derivative is preferably represented by the following formula (III):

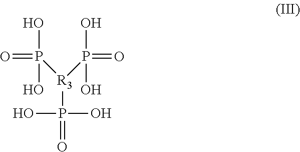

wherein R₃ is a trivalent organic group having one or more carbon atoms.

Such a quantum dot composition prevents reduction in fluorescence emission efficiency and improves stability.

In this case, it is preferable that the phosphonic acid derivative be nitrilotris(methylenephosphonic acid).

Such a phosphonic acid derivative can be used in the quantum dot composition of the present invention.

In this case, the phosphonic acid derivative is preferably represented by the following formula (IV):

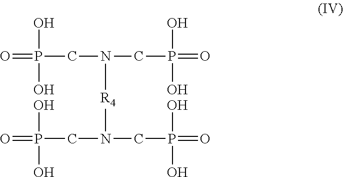

wherein R₄ is a divalent organic group having one or more carbon atoms.

Such a quantum dot composition prevents reduction in fluorescence emission efficiency and improves stability.

In this case, it is preferable that the phosphonic acid derivative be N,N,N′,N′-ethylenediaminetetrakis(methylenephosphonic acid).

Such a phosphonic acid derivative can be used in the quantum dot composition of the present invention.

In this case, it is preferable that the R₁ comprise at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

Such phosphonic acid derivatives can be used in the quantum dot composition of the present invention.

In this case, it is preferable that the R₂ comprise at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

Such phosphonic acid derivatives can be used in the quantum dot composition of the present invention.

In this case, it is preferable that the R₃ comprise at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

Such phosphonic acid derivatives can be used in the quantum dot composition of the present invention.

In this case, it is preferable that the R₄ comprise at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

Such phosphonic acid derivatives can be used in the quantum dot composition of the present invention.

In addition, the present invention provides a resin composition comprising the quantum dot composition described above dispersed in a resin.

Such a resin composition is a resin composition preventing reduction in fluorescence emission efficiency.

In this case, the resin is preferably at least one selected from an epoxy resin, an acrylic resin, a fluororesin, a silicone resin, a carbonate resin, and a glass resin.

Such resins can be used in the resin composition of the present invention.

In addition, the present invention provides a wavelength conversion material comprising a cured product of the resin composition described above.

Such a wavelength conversion material prevents reduction in fluorescence emission efficiency and improves reliability.

### Advantageous Effects of Invention

As described above, the quantum dot composition, the resin composition including the quantum dot composition, and the wavelength conversion material of the present invention prevent reduction in fluorescence emission efficiency, despite using low-toxicity quantum dots.

### DESCRIPTION OF EMBODIMENTS

The present invention is described in detail below, but is not limited thereto.

As described above, there has been a need for a quantum dot composition that prevents reduction in fluorescence emission efficiency despite using low-toxicity quantum dots.

As a result of extensive research into the above-described problem, the present inventors have found that a quantum dot composition including a quantum dot that emits fluorescence by excitation light, in which the quantum dot includes a semiconductor nanoparticle core and a semiconductor nanoparticle shell that do not contain Cd and Pb, and in which a surface of the quantum dot is coated with a metal oxide, and the surface of the quantum dot or a surface of the metal oxide is modified with a phosphonic acid derivative, can prevent reduction in fluorescence emission efficiency despite using low-toxicity quantum dots, and thus completed the present invention.

As described above, there has been a need for a resin composition including a quantum dot composition that prevents reduction in fluorescence emission efficiency despite using low-toxicity quantum dots.

As a result of extensive research into the above-described problem, the present inventors have found that a resin composition including the quantum dot composition described above dispersed in a resin can prevent reduction in fluorescence emission efficiency despite using low-toxicity quantum dots, and thus completed the present invention.

Further, as described above, there has been a need for a wavelength conversion material that uses low-toxicity quantum dots and prevents reduction in fluorescence emission efficiency.

As a result of extensive research into the above-described problem, the present inventors have found that a wavelength conversion material including a cured product of the resin composition described above can prevent reduction in fluorescence emission efficiency despite using low-toxicity quantum dots, and thus completed the present invention.

Embodiments of the present invention are described below. It is noted that in the present invention, the composition, type, and manufacturing method of the quantum dot, metal oxide, and phosphonic acid derivative are not limited to the following embodiments.

That is, the present invention is a quantum dot composition including a quantum dot that emits fluorescence by excitation light, in which the quantum dot includes a semiconductor nanoparticle core and a semiconductor nanoparticle shell that do not contain Cd and Pb, and in which a surface of the quantum dot is coated with a metal oxide, and the surface of the quantum dot or a surface of the metal oxide is modified with a phosphonic acid derivative.

### [Quantum Dot]

The structure of the quantum dot of the present invention is not particularly limited, as long as it is composed of a semiconductor nanoparticle core and a semiconductor nanoparticle shell. Such quantum dots have excellent fluorescence emission properties and stability. For example, in semiconductor nanoparticles with a core-shell structure, in which a nanosized semiconductor particle serves as the core and a semiconductor particle with a larger band gap and lower lattice mismatch than the core serves as the shell, excitons generated in the shell are confined inside the core particle, improving fluorescence emission efficiency, and further, the core surface is covered by the shell, thus improving stability.

In addition, it is preferable that the quantum dot include the semiconductor nanoparticle core and a single or a plurality of the semiconductor nanoparticle shells covering the semiconductor nanoparticle core. Such a quantum dot composition further prevents reduction in fluorescence emission efficiency.

The material for the semiconductor nanoparticle core of the core-shell semiconductor nanoparticles is not particularly limited as long as it does not contain the elements of Cd or Pb, from the viewpoint of toxicity. For example, a material selected from the group consisting of II-VI group compounds, III-V group compounds, I-III-VI group compounds, II-IV-V group compounds, and alloys or mixed crystals thereof can be used.

Specific examples of the material for the semiconductor nanoparticle core include one or more selected from ZnS, ZnSe, ZnTe, AlN, AlP, AlAs, AlSb, GaN, GaP, GaAs, GaSb, InN, InP, InAs, InSb, AgGaS₂, AgInS₂, AgGaSe₂, AgInSe₂, CuGaS₂, CuGaSe₂, CuInS₂, CuInSe₂, ZnSiP₂, and ZnGeP₂, or a mixed crystal thereof. Among these materials, ZnSe, ZnTe, and InP are particularly preferable in terms of the fluorescence emission properties and stability.

In addition, it is preferable that the surface of the core particle of the core-shell semiconductor nanoparticles be passivated with an inorganic compound. This inactivates defects on the surface of the core particle, improving the fluorescence emission efficiency and preventing reduction in the fluorescence emission efficiency over time.

The inorganic compound used for passivation is not particularly limited, and examples thereof include metal halides, and from the viewpoint of improving fluorescence emission efficiency, at least one compound selected from GaCl₃, GaI₃, GaBr₃, ZnCl₂, ZnBr₂, ZnI₂, InCl₃, InBr₃, InI₃, AgCl, AgBr, AgI, KCl, KBr, KI, NaCl, NaBr, NaI, MgCl₂, MgBr₂, MgI₂, CaCl₂, CaBr₂, CaI₂, MnCl₂, MnBr₂, MnI₂, FeCl₂, FeBr₂, FeI₂, CuCl₂, CuBr₂, CuI₂, ZrCl₄, ZrBr₄, ZrI₄, GeCl₄, GeBr₄, and GeI₄ is particularly preferable.

The material for the semiconductor nanoparticle shell is not particularly limited as long as it does not contain the elements of Cd or Pb from the viewpoint of toxicity. The material with a large band gap and low lattice mismatch with respect to the core material is preferable, and the material selected from the group consisting of an alloy and a mixed crystal of II-VI group compounds and III-V group compounds can be used.

As specific shell materials, one or more selected from ZnS, ZnSe, ZnTe, AlN, AlP, AlAs, AlSb, GaN, GaP, GaAs, GaSb, InN, InP, InAs, and InSb or a mixed crystal thereof can be used. Among these materials, ZnSe and ZnS are particularly preferable in terms of improving the fluorescence emission efficiency and stability.

The method for manufacturing semiconductor nanoparticles includes a variety of methods, such as liquid-phase and gas-phase methods, and is not particularly limited in the present invention. From the viewpoint of exhibiting high fluorescence emission efficiency, it is preferable to use semiconductor nanoparticles obtained using the hot soap method or hot injection method, in which precursor species are reacted at high temperatures in a high-boiling-point nonpolar solvent.

Note that in order to reduce surface defects during and after synthesis, quantum dots preferably have organic ligands, referred to as ligands, coordinated to the surfaces thereof.

The ligands preferably include an aliphatic hydrocarbon from the viewpoint of preventing aggregation of quantum dots. Examples of such ligands include oleic acid, stearic acid, palmitic acid, myristic acid, lauric acid, decanoic acid, octanoic acid, oleylamine, stearyl (octadecyl)amine, dodecyl (lauryl) amine, decylamine, octylamine, octadecanethiol, hexadecanethiol, tetradecanethiol, dodecanethiol, decanethiol, octanethiol, trioctylphosphine, trioctylphosphine oxide, triphenylphosphine, triphenylphosphine oxide, tributylphosphine, and tributylphosphine oxide, and these may be used singly or in combination.

[Coating Surface of the Quantum Dots with Metal Oxide]

The surfaces of the quantum dots of the present invention are coated with a metal oxide, which prevents oxygen and water in the atmosphere from coming into direct contact with the surface of the quantum dots, and this inhibits oxidation reactions and is considered to prevent reduction in the fluorescence emission efficiency thereof.

In the present invention, the “coating” of the surface of the quantum dots with a metal oxide may be in the form of partial or complete coating, as long as the reduction in the fluorescence emission efficiency over time is prevented. In addition, the coating may be a uniform coating layer such as a core-shell structure, or a non-uniform coating layer, or may have a structure in which a plurality of semiconductor nanoparticles are coated with a metal oxide. The thickness of the metal oxide film is not particularly limited, and from the viewpoint of translucency, the thickness is preferably 200 nm or less.

In the present invention, the type of the oxide coating layer is not particularly limited, and examples thereof include at least one compound selected from TiO₂, ZnO, Al₂O₃, SiO₂, ZrO₂, Fe₂O₃, MgO, Y₂O₃, HfO₂, CeO₂, In₂O₃, SnO₂, WO₃, CrO₃, Ta₂O₃, BaTiO₃, V₂O₅, NiO, NbO, Cu₂O, CuO, and MoO₃. From the viewpoint of improving the stability of the quantum dots, TiO₂, Al₂O₃, SiO₂, and ZrO₂ are more preferable.

The method for forming the metal oxide coating layer is not particularly limited, and from the viewpoint of selectively promoting the reaction on the surface of the quantum dots, a method for reacting a metal oxide precursor in a liquid phase is preferable.

One example of a method for forming an oxide coating layer using microwave treatment is described in the present invention. The use of microwaves can heat the metal oxide precursor directly from the inside, allowing the reaction to proceed selectively in a shorter time, resulting in the formation of an oxide layer on the surface of the quantum dots.

Herein, “microwaves” generally refers to electromagnetic waves with a frequency of 300 MHz to 3 THz. In addition, examples of microwave irradiation methods include, but are not limited to, a method using flexiWAVE manufactured by Milestone General K. K.

In this case, it is preferable that the coating step be performed in the coexistence of quantum dots and a metal oxide precursor, and to irradiate the coexisting metal oxide precursor with microwaves to coat the surfaces of the semiconductor nanoparticles with a metal oxide. This allows for efficient formation of a metal oxide coating layer, preventing reduction in fluorescence emission efficiency.

In this case, it is preferable that one or more of a polar solvent, a non-polar solvent, and an ionic liquid be selected as the dispersion medium for the quantum dots and metal oxide precursor, and the coating layer be formed in that solvent.

In addition, it is preferable to use one or more of toluene, hexane, cyclohexane, benzene, and diethyl ether as the solvent used in this coating step. These non-polar solvents can further improve the dispersibility of the semiconductor nanoparticles.

When the solvent is non-polar, a microwave-absorbing heating element called Weflon, a type of PTFE resin including carbon components manufactured by Milestone General K.K., may optionally be used during the coating step.

The metal oxide precursor is not particularly limited, and it is preferable to use one or more selected from metal alkoxides, metal halides, and metal complexes. From the viewpoint of stability, silicon alkoxides, aluminum alkoxides, zirconium alkoxides, and titanium alkoxides are particularly preferable as metal oxide precursors.

In this case, it is preferable to use a catalyst to promote the reaction of the metal oxide precursor during the coating step. In particular, when using a metal alkoxide, it is desirable to use a catalyst to promote the sol-gel reaction. Examples of the catalyst include an acidic or basic aqueous solution, and the basic aqueous solution is particularly preferable from the viewpoint of the layer thickness of the coating layer.

In addition, a surfactant may be added during the coating step from the viewpoint of the dispersibility of the metal oxide precursor. The surfactant is not particularly limited, and examples thereof include quaternary ammonium salts such as cetyltrimethylammonium bromide, which are cationic surfactants; carboxylates and sulfonates, which are anionic surfactants; polyoxyethylene alkyl ethers, which are nonionic surfactants; and cetyltrimethylammonium bromide. The cationic surfactant is particularly preferable from the viewpoint of the dispersibility of the metal oxide precursor.

In addition, it is preferable to perform the coating step in the presence of alcohol. Coating in the presence of alcohol provides superior dispersibility of the metal oxide precursor. In addition, when a surfactant is added, dissolving the surfactant in a polar solvent such as alcohol can further improve dispersibility.

The reaction temperature in the microwave irradiation treatment varies depending on the solvent, and is preferably 40 to 200° C., and more preferably 50 to 110° C., from the viewpoint of preventing reduction in fluorescence emission efficiency.

The microwave treatment is used as an example of the oxide coating step in this embodiment, but is not particularly limited as long as it is a method for “coating” the surface of the quantum dots with an oxide layer.

### [Phosphonic Acid Derivative]

As described above, in this embodiment, a metal oxide precursor is reacted in a solution to form a metal oxide coating layer on the surface of the quantum dots, thereby preventing water and oxygen in the atmosphere from coming into direct contact with the surface of the quantum dots, and preventing reduction in fluorescence emission efficiency.

However, after the oxide coating layer is formed, numerous hydroxy groups remain on the outer surface of the oxide. Upon contact with water in the atmosphere, these hydroxy groups form hydrogen bonds, forming a nano-scale thin layer of adsorbed water, known as a hydration layer, on the surface of the oxide.

It is considered that when a composition in which the surface of quantum dots is coated with an oxide as described above is used as a wavelength conversion material, the composition is exposed to external stimuli such as light and heat for long periods of time, and thus this adsorbed water gradually penetrates into the surfaces of the internal quantum dots, promoting surface oxidation and resulting in reduction in fluorescence emission efficiency over long-term use. To prevent this reduction in fluorescence emission efficiency, it is preferable to remove as many hydroxy groups as possible from the surface of the oxide.

However, it is difficult to completely remove the hydroxy groups on the surface of the metal oxide by heating. Depending on the composition of the metal oxide, heating to approximately 500° C. or more is required. Heating at this temperature zone causes changes in the quantum dot morphology and reduction or loss of the emission efficiency, thus making it difficult to remove the hydroxy groups by heating alone.

Therefore, a phosphonic acid derivative is a useful modifier necessary for removing the hydroxy groups on the surface of the oxide in this invention, and the quantum dot composition in this embodiment is composed of the above quantum dots, an oxide coating the surfaces of the quantum dots, and the phosphonic acid derivative that modifies the surface of the quantum dots or the surface of the oxide.

Phosphonic acid derivatives themselves are stable compounds and do not self-polymerize, and thus do not deposit in the bulk. They selectively adhere to and modify the surface of the oxide or surfaces of the quantum dots.

In particular, on the surface of the oxide, heat treatment at several tens of degrees causes a dehydration condensation reaction between the hydroxy groups of the metal oxide and the phosphonic acid derivative, thus removing the hydroxy groups on the surface of the oxide and modifying the surface of the oxide with the phosphonic acid derivative.

Further, H⁺ (protons) are continuously donated from the OH groups of the phosphonic acid derivative to the dangling bond of oxygen on the surface of the oxide, and thus the above dehydration condensation reaction occurs repeatedly, and the surface of the oxide is densely modified with the phosphonic acid derivative.

In this embodiment, “modification” refers to a state in which phosphonic acid adheres to the surface of the metal oxide or the surface of the quantum dots. The adhesion of the phosphonic acid derivative to the surface by “modification” includes partial and full-surface adhesion, and refers to a state of adhesion to at least a portion of the surface.

The above-described “adhesion” may be physical adsorption or chemical bonding, and broadly refers to covalent bonds, ionic bonds, and hydrogen bonds, for example, or may be combinations thereof.

In addition, as an example, the quantum dot composition described above, which is composed of quantum dots, an oxide coating layer, and modifications with a phosphonic acid derivative, may be in a state in which the organic ligands attached to the surface of the metal oxide or the quantum dots during synthesis coexist with the phosphonic acid derivative.

The type of the phosphonic acid derivative is not particularly limited, and for example, the structure of this compound is preferably represented by at least one of the following formulae (I), (II), (III), and (IV).

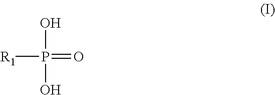

In the formula (I), R₁ is a monovalent organic group having one or more carbon atoms.

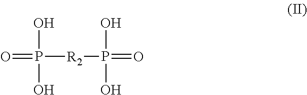

In the formula (II), R₂ is a divalent organic group having one or more carbon atoms.

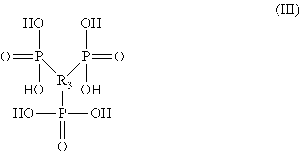

In the formula (III), R₃ is a trivalent organic group having one or more carbon atoms.

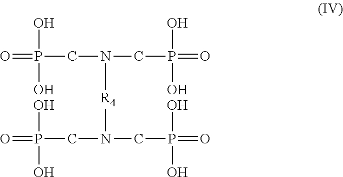

In the formula (IV), R₄ is a divalent organic group having one or more carbon atoms.

In certain embodiments of the compounds of the formulae (I) to (IV), R₁ to R₄ preferably include at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

Specific examples of the formula (I) include 3-phenyl-2-propynylphosphonic acid, tenofovir, 2-phosphonobutane-1,2,4-tricarboxylic acid, 4-phosphonobenzoic acid, vinylphosphonic acid, n-octylphosphonic acid, (3-bromopropyl)phosphonic acid, (4-bromobutyl)phosphonic acid, (2-bromoethyl)phosphonic acid, (4-bromophenyl)phosphonic acid, 3-phosphonopropionic acid, (4-hydroxyphenyl)phosphonic acid, hexylphosphonic acid, 4-phosphonobutyric acid, propylphosphonic acid, (4-aminobenzyl)phosphonic acid, (4-aminophenyl)phosphonic acid, 3-phosphonobenzoic acid, methylphosphonic acid, nonylphosphonic acid, benzhydrylphosphonic acid, octadecylphosphonic acid, (aminomethyl)phosphonic acid, (2-phenylethyl)phosphonic acid, ethylphosphonic acid, butylphosphonic acid, decylphosphonic acid, dodecylphosphonic acid, (2-chloroethyl)phosphonic acid, 4-methoxyphenylphosphonic acid, hexadecylphosphonic acid, (4-hydroxybenzyl)phosphonic acid, phenylphosphonic acid, (1H,1H,2H,2H-heptadecafluorodecyl)phosphonic acid, tetradecylphosphonic acid, (1-aminoethyl)phosphonic acid, undecylphosphonic acid, heptylphosphonic acid, 10-carboxydecylphosphonic acid, 11-aminoundecylphosphonic acid hydrobromide, 11-hydroxyundecylphosphonic acid, 1H,1H,2H,2H-perfluoro-n-hexylphosphonic acid, 1H,1H,2H,2H-perfluorooctylphosphonic acid, 1H,1H,2H,2H-perfluoro-n-decylphosphonic acid, 11-{2-[2-(2-methoxyethoxy)ethoxy]ethoxy}undecylphosphonic acid, 12-mercaptodecylphosphonic acid, and [11-(acryloyloxy)undecyl]phosphonic acid.

Specific examples of the formula (II) include m-xylylenediphosphonic acid, o-xylylenediphosphonic acid, methylenediphosphonic acid, alendronic acid, 1,4-butylenediphosphonic acid, glycine-N,N-bis(methylenephosphonic acid), p-xylylenediphosphonic acid, zoledronic acid, 1,3-propylenediphosphonic acid, 1,5-pentylenediphosphonic acid, 1,4-phenylenediphosphonic acid, 1,2-ethylenediphosphonic acid, 1,6-hexylenediphosphonic acid, minodronate, and 1-hydroxyethane-1,1-diphosphonic acid.

Specific examples of the formula (III) include nitrilotris(methylenephosphonic acid).

Specific examples of the formula (IV) include N,N,N′,N′-ethylenediaminetetrakis(methylenephosphonic acid).

The above phosphonic acid derivatives can be used singly or in combination of two or more.

The heating temperature upon modification of the surface of the quantum dots or the surface of the metal oxide with the above phosphonic acid derivative is not particularly limited, and to achieve efficient modification, the heating temperature is preferably in the range of 50 to 300° C., and more preferably in the range of 80 to 200° C. Within these ranges, more efficient modification can be achieved on surfaces of the quantum dots.

The amount of phosphonic acid derivative added as the above surface modifier is not particularly limited, as long as it is within the range in which the phosphonic acid derivative modifies the surface of the quantum dots or the surface of the metal oxide. For example, an amount of 30 wt % or less is preferable because aggregation of quantum dots and deposition of the phosphonic acid derivative can be prevented, and an amount of 0.01 wt % or more allows the effect of modifying the surface of the quantum dots or the surface of the metal oxide to be fully exerted. Accordingly, the weight of the surface modifier added is preferably in the range of 0.01 to 30 wt %, and more preferably 0.05 to 20 wt %, relative to the solid weight of the quantum dots.

### [Quantum Dot Composition]

In the quantum dot composition in which the surface of the quantum dots is coated with the oxide layer described above and the surface of the quantum dots or the oxide layer surface is modified with a phosphonic acid, oxidation reaction on the surface of the quantum dots is prevented, thereby preventing reduction in the fluorescence emission efficiency and improving stability.

### [Resin Composition]

In addition, it is possible to use the resin composition in which the above-described quantum dot composition is dispersed in a resin. The resin material is not particularly limited, and the preferable resin material is a material in which the quantum dot composition does not aggregate and the fluorescence emission efficiency does not deteriorate, and examples thereof include at least one or more selected from an epoxy resin, an acrylic resin, a fluororesin, a silicone resin, a carbonate resin, and a glass resin.

In order to increase the fluorescence emission efficiency, these resin compositions preferably have high transmittance, and a transmittance of 80% or more is particularly preferable.

In addition, the concentration of quantum dots included in the resin composition is not particularly limited and can be appropriately adjusted for the film thickness, the emission efficiency of the quantum dot, and the desired properties of the wavelength conversion material.

In addition, the resin composition may include substances other than the quantum dot composition, such as fine particles of silica, zirconia, alumina, and titania as light scatterers, or an inorganic phosphor or organic phosphor.

Examples of the inorganic phosphor include YAG, LSN, LYSN, CASN, SCASN, KSF, CSO, β-SIALON, GYAG, LuAG, and SBCA, and examples of the organic phosphor include a perylene derivative, an anthraquinone derivative, an anthracene derivative, a phthalocyanine derivative, a cyanine derivative, a dioxazine derivative, a benzoxazinone derivative, a coumarin derivative, a quinophthalone derivative, a benzoxazole derivative, and a pyrralizine derivative.

### [Wavelength Conversion Material]

In addition, the present invention provides a wavelength conversion material including a cured product of the above-described resin composition. The wavelength conversion material may be used as is or may be processed. One form is a wavelength conversion film in which the quantum dot composition is dispersed in the resin, the film obtained by processing the resin into a sheet, which is then cured.

The method for manufacturing the wavelength conversion material is not particularly limited, and for example, a wavelength conversion material can be obtained by applying a resin composition in which a quantum dot composition is dispersed onto a transparent film such as PET or polyimide, curing the resin composition, which is then subjected to lamination processing.

As the application onto the transparent film, a spraying method such as spraying or inkjet, a spin coating method, a bar coating method, or a doctor blade method can be used, and the application forms a resin layer. In addition, the thicknesses of the resin layer and the transparent film are not particularly limited and can be selected appropriately depending on use. Such a wavelength conversion material prevents reduction in the fluorescence emission efficiency and improves reliability.

### EXAMPLE

The present invention will be specifically explained below using manufacturing examples, examples, and comparative examples, but the present invention is not limited thereto.

### (Evaluation of Emission Properties)

In the manufacturing examples, examples, and comparative examples, the fluorescence emission properties of quantum dots, quantum dot compositions, and wavelength conversion materials were evaluated by measuring the fluorescence emission efficiency (internal quantum efficiency) at an excitation wavelength of 450 nm using a quantum efficiency measurement system (QE-2100) manufactured by Otsuka Electronics Co., Ltd.

### Manufacture of Quantum Dot

### Manufacturing Example 1

0.070 g (0.24 mmol) of indium acetate, 0.256 g (0.72 mmol) of palmitic acid, and 4.0 mL of 1-octadecene were charged into a flask, and the mixture was heated and stirred at 100° C. under reduced pressure for degassing for 1 hour while performing dissolution. The flask was cooled to room temperature, then purged with nitrogen, and 0.50 mL (0.17 mmol) of a 10 vol % (tris)trimethylsilylphosphine/octadecene solution was added to the flask. The flask was heated to 300° C. and stirring was performed for 20 minutes to synthesize InP semiconductor core particles.

The flask was then cooled to 200° C., after that 0.10 mL (0.02 mmol) of a gallium (III) chloride/octadecene solution was added and the mixture was heated for 30 minutes to passivate the surface of the InP semiconductor core particles.

Further, the flask was heated to 240° C., after that 4.0 mL (1.2 mmol) of a 0.30 M zinc stearate/octadecene solution was added and the mixture was stirred for 30 minutes. Further, 0.60 mL (0.90 mmol) of a 1.5 M selenium/trioctylphosphine solution was added to the flask, and the mixture was stirred for 30 minutes.

The flask was then cooled to room temperature, and then 0.22 g (1.1 mmol) of zinc acetate was added, the mixture was heated and stirred at 100° C. under reduced pressure for degassing for 1 hour while performing dissolution. The flask was purged with nitrogen and the mixture was then heated to 230° C., and 0.48 mL (2.0 mmol) of 1-dodecanethiol was added and the mixture was stirred for 30 minutes.

The resulting solution was cooled to room temperature, ethanol was added, the mixture was centrifuged to precipitate quantum dots composed of an InP core, a ZnSe shell, and a ZnS shell, and the supernatant was then removed.

Toluene was further added to the precipitate, which was then dispersed, ethanol was added again, the mixture was centrifuged, the supernatant was removed, and the precipitate was redispersed in toluene to prepare an InP/ZnSe/ZnS dispersion.

The resulting InP/ZnSe/ZnS toluene dispersion had a peak wavelength of fluorescence emission of 535 nm and an internal quantum efficiency of 84%. In addition, the InP/ZnSe/ZnS toluene dispersion was irradiated with blue light at a wavelength of 450 nm using a blue LED light source (HL-36, manufactured by AS ONE Corporation) in an air atmosphere for 12 hours, and then the fluorescence emission efficiency was measured, resulting in an internal quantum efficiency of 68%.

### Manufacturing Example 2

0.033 g (0.20 mmol) of silver (I) acetate, 0.058 g (0.20 mmol) of indium acetate, 0.65 mL (2.7 mmol) of 1-dodecanethiol, and 4.0 mL of oleylamine were charged into a flask, and the mixture was heated and stirred at 100° C. under reduced pressure for degassing for 1 hour. The flask was then purged with nitrogen, and the mixture was heated to 200° C. and held for 20 minutes to synthesize AgInS₂ semiconductor core particles.

Then, 0.014 g (0.1 mmol) of zinc chloride was dissolved in 1.0 mL of trioctylphosphine solution, and the solution was added to the flask heated to 200° C. to passivate the surface of the AgInS₂ semiconductor core particles.

Then, the flask was heated to 230° C., and a 1.25 M sulfur/trioctylphosphine solution was prepared, 1.0 mL of the solution was added to the reaction solution, and the mixture was stirred for 1 hour. Finally, a zinc precursor solution prepared by dissolving 0.099 g (0.54 mmol) of zinc acetate in 0.24 mL (0.76 mmol) of oleic acid and 0.15 mL of oleylamine was added to the flask, and the mixture was heated and stirred at 230° C. for 1 hour.

The resulting solution was cooled to room temperature, ethanol was added, and the mixture was centrifuged to precipitate the quantum dots, and the supernatant was removed. Toluene was further added to disperse the quantum dots, and ethanol was added again, followed by centrifugation, the supernatant was removed, and the precipitate was redispersed in toluene to prepare an AgInS₂/ZnS dispersion.

The resulting AgInS₂/ZnS toluene dispersion had a fluorescence emission wavelength peak of 599 nm and an internal quantum efficiency of 68%. In addition, the AgInS₂/ZnS dispersion was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 49%.

### Formation of Metal-Oxide Coating Layer

### Manufacturing Example 3

10 g of the toluene solution of 1.0 wt % InP/ZnSe/ZnS quantum dots (semiconductor nanoparticles) obtained in Manufacturing Example 1, 110 μL of tetraethyl orthosilicate, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, manufactured by Milestone General K. K.), the mixture was heated at 60° C. for 5 minutes at 2450 MHz to form a SiO₂ coating layer on the InP/ZnSe/ZnS surface. Ethanol was added to the resulting nanoparticles, which were then centrifuged for sedimentation, the supernatant was removed, toluene or octadecene was added, and the mixture was redispersed by ultrasonic irradiation.

The internal quantum efficiency of the resulting InP/ZnSe/ZnS/SiO₂ toluene dispersion was 81%. In addition, the InP/ZnSe/ZnS/SiO₂ toluene dispersion was irradiated with blue light at a wavelength of 450 nm using a blue LED light source (HL-36, manufactured by AS ONE Corporation) in an air atmosphere for 12 hours, and then the fluorescence emission efficiency was measured, resulting in an internal quantum efficiency of 71%.

### Manufacturing Example 4

10 g of the toluene solution of 1.0 wt % InP/ZnSe/ZnS quantum dots (semiconductor nanoparticles) obtained in Manufacturing Example 1, 0.10 g of aluminum isopropoxide, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, manufactured by Milestone General K.K.), heating was performed at 60° C. for 5 minutes at 2450 MHz to form an Al₂O₃ coating layer on the InP/ZnSe/ZnS surface. Ethanol was added to the resulting nanoparticles, which were then centrifuged for sedimentation, the supernatant was removed, toluene or octadecene was added, and the mixture was subjected to ultrasonic irradiation to redisperse the nanoparticles.

The internal quantum efficiency of the resulting InP/ZnSe/ZnS/Al₂O₃ toluene dispersion was 83%. In addition, the InP/ZnSe/ZnS/Al₂O₃ toluene dispersion was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 72%.

### Manufacturing Example 5

10 g of the toluene solution of 1.0 wt % InP/ZnSe/ZnS quantum dots (semiconductor nanoparticles) obtained in Manufacturing Example 1, 0.16 g of zirconium (IV) isopropoxide, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, manufactured by Milestone General K.K.), heating was performed at 60° C. for 5 minutes at 2450 MHz to form a ZrO₂ coating layer on the InP/ZnSe/ZnS surface. Ethanol was added to the resulting nanoparticles, which were then centrifuged for sedimentation, the supernatant was removed, toluene or octadecene was added, and the mixture was subjected to ultrasonic irradiation to redisperse the nanoparticles.

The internal quantum efficiency of the resulting InP/ZnSe/ZnS/ZrO₂ toluene dispersion was 83%. In addition, the InP/ZnSe/ZnS/ZrO₂ toluene dispersion was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 73%.

### Manufacturing Example 6

10 g of the toluene solution of 1.0 wt % InP/ZnSe/ZnS quantum dots (semiconductor nanoparticles) obtained in Manufacturing Example 1, 0.14 g of titanium tetraisopropoxide, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, manufactured by Milestone General K.K.), heating was performed at 60° C. for 5 minutes at 2450 MHz to form a TiO₂ coating layer on the InP/ZnSe/ZnS surface.

Ethanol was added to the resulting nanoparticles, which were then centrifuged for sedimentation, the supernatant was removed, toluene or octadecene was added, and the mixture was subjected to ultrasonic irradiation to redisperse the nanoparticles.

The internal quantum efficiency of the resulting InP/ZnSe/ZnS/TiO₂ toluene dispersion was 78%. In addition, the InP/ZnSe/ZnS/TiO₂ toluene dispersion was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 70%.

### Manufacturing Example 7

10 g of the toluene solution of 1.0 wt % AgInS₂/ZnS quantum dots (semiconductor nanoparticles) obtained in Manufacturing Example 2, 0.10 g of aluminum isopropoxide, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, Milestone General K.K.), heating was performed at 60° C. for 5 minutes at 2450 MHz to form an Al₂O₃ coating layer on the AgInS₂/ZnS surface. Ethanol was added to the resulting nanoparticles, which were then centrifuged for sedimentation, the supernatant was removed, toluene or octadecene was added, and the mixture was subjected to ultrasonic irradiation to redisperse the nanoparticles.

The internal quantum efficiency of the resulting AgInS₂/ZnS/Al₂O₃ toluene dispersion was 64%. In addition, the AgInS₂/ZnS/Al₂O₃ toluene dispersion was irradiated with blue light at a wavelength of 450 nm using a blue LED light source (HL-36, AS ONE Corporation) for 12 hours in an air atmosphere, and then the fluorescence emission efficiency was measured, resulting in an internal quantum efficiency of 54%.

### Manufacturing Example 8

10 g of the toluene solution of 1.0 wt % AgInS₂/ZnS quantum dots (semiconductor nanoparticles) obtained in Manufacturing Example 2, 0.16 g of zirconium (IV) isopropoxide, 50 μL of 25% aqueous ammonia, and 0.010 g/100 μL of cetyltrimethylammonium bromide/ethanol solution were mixed and charged into a high-pressure reactor.

Then, using a microwave synthesis reaction apparatus (flexiWAVE, Milestone General K.K.), heating was performed at 60° C. for 5 minutes at 2450 MHz to form a ZrO₂ coating layer on the AgInS₂/ZnS surface. Ethanol was added to the resulting nanoparticles, which were then centrifuged for sedimentation, the supernatant was removed, toluene or octadecene was added, and the mixture was subjected to ultrasonic irradiation to redisperse the nanoparticles.

The internal quantum efficiency of the resulting AgInS₂/ZnS/ZrO₂ toluene dispersion was 63%. In addition, the AgInS₂/ZnS/ZrO₂ toluene dispersion was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 53%.

### Surface Modification with Phosphonic Acid Derivative

### Example 1

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % InP/ZnSe/ZnS/SiO₂ octadecene dispersion obtained in Manufacturing Example 3 and 6 ml of the hexadecylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which InP/ZnSe/ZnS/SiO₂ was modified with HDPA. The resulting solution was cooled to room temperature, ethanol was added, and the mixture was centrifuged to precipitate the quantum dot composition, and the supernatant was removed.

Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 81%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 76%.

### Example 2

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % InP/ZnSe/ZnS/Al₂O₃ octadecene dispersion obtained in Manufacturing Example 4 and 6 ml of the hexadecylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which InP/ZnSe/ZnS/Al₂O₃ was modified with HDPA.

The resulting solution was cooled to room temperature, ethanol was added, the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 82%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 80%.

### Example 3

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % InP/ZnSe/ZnS/ZrO₂ octadecene dispersion obtained in Manufacturing Example 5 and 6 ml of the hexadecylphosphonic acid solution were added into a three-neck flask. The flask was then heated and stirred at 50° C. under reduced pressure for degassing for 10 minutes.

Then, the flask was purged with nitrogen, heated to 150° C., and stirring was performed for 3 hours to obtain a quantum dot composition in which InP/ZnSe/ZnS/ZrO₂ was modified with HDPA.

The resulting solution was cooled to room temperature, ethanol was added, the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 82%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and the fluorescence emission efficiency was measured, resulting in an internal quantum efficiency of 79%.

### Example 4

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % InP/ZnSe/ZnS/TiO₂ octadecene dispersion obtained in Manufacturing Example 6 and 6 ml of the hexadecylphosphonic acid solution were added into a three-neck flask.

The flask was then heated and stirred at 50° C. under reduced pressure for degassing for 10 minutes. Then, the flask was purged with nitrogen, and the mixture was heated to 150° C. and stirring was performed for 3 hours to obtain a quantum dot composition in which InP/ZnSe/ZnS/TiO₂ was modified with HDPA.

The resulting solution was cooled to room temperature, ethanol was added, the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 78%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 77%.

### Example 5

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % AgInS₂/ZnS/Al₂O₃ octadecene dispersion obtained in Manufacturing Example 7 and 6 ml of the hexadecylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which AgInS₂/ZnS/Al₂O₃ was modified with HDPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 63%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 61%.

### Example 6

In a nitrogen atmosphere, 31 mg of hexadecylphosphonic acid (HDPA) was weighed into a 20-ml vial, and 5 ml of toluene and 1 ml of ethanol were added and stirred to prepare a hexadecylphosphonic acid solution.

Further, under a nitrogen atmosphere, 10 g of the 1.0 wt % AgInS₂/ZnS/ZrO₂ octadecene dispersion obtained in Manufacturing Example 8 and 6 ml of the hexadecylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which AgInS₂/ZnS/ZrO₂ was modified with HDPA.

The resulting solution was cooled to room temperature, ethanol was added, the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 65%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 62%.

### Example 7

In a nitrogen atmosphere, 25 mg of dodecylphosphonic acid (DDPA) was weighed into a 20-ml vial, and 5 ml of toluene and 1 ml of ethanol were added and stirred to prepare a dodecylphosphonic acid solution.

Further, under a nitrogen atmosphere, 10 g of the 1.0 wt % InP/ZnSe/ZnS/Al₂O₃ octadecene dispersion obtained in Manufacturing Example 4 and 6 ml of the dodecylphosphonic acid solution were added into a three-neck flask.

The flask was then heated and stirred at 50° C. under reduced pressure for degassing for 10 minutes. The flask was then purged with nitrogen, and heated to 150° C. and stirring was performed for 3 hours to obtain a quantum dot composition in which InP/ZnSe/ZnS/Al₂O₃ was modified with DDPA.

The resulting solution was cooled to room temperature, ethanol was added, and the mixture was centrifuged to precipitate the quantum dot composition, the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 82%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 79%.

### Example 8

In a nitrogen atmosphere, 22 mg of (4-bromobutyl)phosphonic acid (BBPA) was weighed into a 20-ml vial, and 5 ml of toluene and 1 ml of ethanol were added and stirred to prepare a (4-bromobutyl)phosphonic acid solution.

Further, under a nitrogen atmosphere, 10 g of the 1.0 wt % InP/ZnSe/ZnS/Al₂O₃ octadecene dispersion obtained in Manufacturing Example 4 and 6 ml of the (4-bromobutyl)phosphonic acid solution were added into a three-neck flask.

Then, the flask was heated and stirred at 50° C. under reduced pressure for degassing for 10 minutes. Then, the flask was purged with nitrogen, heated to 150° C., and stirring was performed for 3 hours to obtain a quantum dot composition in which InP/ZnSe/ZnS/Al₂O₃ was modified with BBPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 81%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 78%.

### Example 9

In a nitrogen atmosphere, 16 mg of phenylphosphonic acid (PhPA) was weighed into a 20-ml vial, and 5 ml of toluene and 1 ml of ethanol were added and stirred to prepare a phenylphosphonic acid (PhPA) solution.

Further, under a nitrogen atmosphere, 10 g of the 1.0 wt % InP/ZnSe/ZnS/Al₂O₃ octadecene dispersion obtained in Manufacturing Example 4 and 6 ml of the phenylphosphonic acid solution were added into a three-neck flask. The flask was then heated and stirred at 50° C. under reduced pressure for degassing for 10 minutes.

Then, the flask was purged with nitrogen, heated to 150° C., and stirring was performed for 3 hours to obtain a quantum dot composition in which InP/ZnSe/ZnS/Al₂O₃ was modified with PhPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 82%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 78%.

### Example 10

In a nitrogen atmosphere, 25 mg of dodecylphosphonic acid (DDPA) was weighed into a 20-ml vial, and 5 ml of toluene and 1 ml of ethanol were added and stirred to prepare a dodecylphosphonic acid solution.

Further, under a nitrogen atmosphere, 10 g of the 1.0 wt % AgInS₂/ZnS/Al₂O₃ octadecene dispersion obtained in Manufacturing Example 7 and 6 ml of the dodecylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which AgInS₂/ZnS/Al₂O₃ was modified with DDPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 63%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 60%.

### Example 11

In a nitrogen atmosphere, 22 mg of (4-bromobutyl)phosphonic acid (BBPA) was weighed into a 20-ml vial, and 5 ml of toluene and 1 ml of ethanol were added and stirred to prepare a (4-bromobutyl)phosphonic acid solution.

Further, under a nitrogen atmosphere, 10 g of the 1.0 wt % AgInS₂/ZnS/Al₂O₃ octadecene dispersion obtained in Manufacturing Example 7 and 6 ml of the (4-bromobutyl)phosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which AgInS₂/ZnS/Al₂O₃ was modified with BBPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 61%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 59%.

### Example 12

In a nitrogen atmosphere, 22 mg of phenylphosphonic acid (PhPA) was weighed into a 20-ml vial, and 5 ml of toluene and 1 ml of ethanol were added and stirred to prepare a phenylphosphonic acid solution.

Further, under a nitrogen atmosphere, 10 g of the 1.0 wt % AgInS₂/ZnS/Al₂O₃ octadecene dispersion obtained in Manufacturing Example 7 and 6 ml of the phenylphosphonic acid solution were added into a three-neck flask.

The flask was then heated and stirred at 50° C. under reduced pressure for degassing for 10 minutes. The flask was then purged with nitrogen, heated to 150° C., and stirring was performed for 3 hours to obtain a quantum dot composition in which AgInS₂/ZnS/Al₂O₃ was modified with PhPA.

The resulting solution was cooled to room temperature, ethanol was added, and the mixture was centrifuged to precipitate the quantum dot composition, and the supernatant was removed. Toluene was further added to the precipitate, which was then dispersed, ethanol was added again, followed by centrifugation, the supernatant was removed, and the precipitate was redispersed in toluene to prepare a toluene dispersion of the quantum dot composition.

The internal quantum efficiency of the resulting toluene dispersion of the quantum dot composition was 63%. In addition, the resulting toluene dispersion of the quantum dot composition was irradiated with blue light at a wavelength of 450 nm using a blue LED light source (HL-36, manufactured by AS ONE Corporation) for 12 hours in an air atmosphere, and then the fluorescence emission efficiency was measured, resulting in an internal quantum efficiency of 60%.

These results are shown in Table 1.

TABLE 1

| | | Toluene dispersion | |
|---|---|---|---|
| | | Internal quantum | Internal quantum |
| | | efficiency before | efficiency after |
| | | blue excitation | blue excitation |
| | Quantum dot or quantum | light irradiation | light irradiation |
| | dot composition | (%) | (%) |
| Manufacturing | InP/ZnSe/ZnS | 84 | 68 |
| Example 1 | | | |
| Manufacturing | AgInS₂/ZnS | 68 | 49 |
| Example 2 | | | |
| Manufacturing | InP/ZnSe/ZnS/SiO₂ | 81 | 71 |
| Example 3 | | | |
| Manufacturing | InP/ZnSe/ZnS/Al₂O₃ | 83 | 72 |
| Example 4 | | | |
| Manufacturing | InP/ZnSe/ZnS/ZrO₂ | 83 | 73 |
| Example 5 | | | |
| Manufacturing | InP/ZnSe/ZnS/TiO₂ | 78 | 70 |
| Example 6 | | | |
| Manufacturing | AgInS₂/ZnS/Al₂O₃ | 64 | 54 |
| Example 7 | | | |
| Manufacturing | AgInS₂/ZnS/ZrO₂ | 63 | 53 |
| Example 8 | | | |
| Example 1 | InP/ZnSe/ZnS/SiO₂/HDPA | 81 | 76 |
| Example 2 | InP/ZnSe/ZnS/Al₂O₃/HDPA | 82 | 80 |
| Example 3 | InP/ZnSe/ZnS/ZrO₂/HDPA | 82 | 79 |
| Example 4 | InP/ZnSe/ZnS/TiO₂/HDPA | 78 | 77 |
| Example 5 | AgInS₂/ZnS/Al₂O₃/HDPA | 63 | 61 |
| Example 6 | AgInS₂/ZnS/ZrO₂/HDPA | 65 | 62 |
| Example 7 | InP/ZnSe/ZnS/Al₂O₃/DDPA | 82 | 79 |
| Example 8 | InP/ZnSe/ZnS/Al₂O₃/BBPA | 81 | 78 |
| Example 9 | InP/ZnSe/ZnS/Al₂O₃/PhPA | 82 | 78 |
| Example 10 | AgInS₂/ZnS/Al₂O₃/DDPA | 63 | 60 |
| Example 11 | AgInS₂/ZnS/Al₂O₃/BBPA | 61 | 59 |
| Example 12 | AgInS₂/ZnS/Al₂O₃/PhPA | 63 | 60 |

Comparing the internal quantum yield values after blue light irradiation for the toluene dispersion of the quantum dots of Manufacturing Example 1 and the toluene dispersions of the metal oxide-coated quantum dots of Manufacturing Examples 3 to 6 with the toluene dispersions of the oxide-coated and phosphonic acid-treated quantum dot compositions of Examples 1 to 4 and 7 to 9, it has been found that the quantum dot compositions of Examples 1 to 4 and 7 to 9 maintained higher internal quantum yield values.

In addition, comparing the internal quantum yield values after blue light irradiation for the toluene dispersion of the quantum dots of Manufacturing Example 2 and the toluene dispersions of the metal oxide-coated quantum dots of Manufacturing Examples 7 and 8 with the toluene dispersions of the oxide-coated and phosphonic acid-treated quantum dot compositions of Examples 5, 6, and 10 to 12, it has been found that the quantum dot compositions of Examples 5, 6, and 10 to 12 maintained higher internal quantum yield values.

These results confirmed that the quantum dots with the surfaces having metal oxide layers formed thereon and modified with phosphonic acid derivatives prevented reduction in the internal quantum yield due to blue light irradiation and improved photostability.

### Preparation of Resin Composition and Wavelength Conversion Material

### Example 13

A wavelength conversion material was manufactured using the quantum dot composition obtained in Example 1. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 97 μm. In addition, the internal quantum efficiency of the obtained wavelength conversion material was 44%. In addition, the obtained wavelength conversion material was treated for 500 hours under conditions of 85° C. and 85% RH (relative humidity), and then the fluorescence emission efficiency was measured, resulting in an internal quantum efficiency of 41%.

### Example 14

A wavelength conversion material was manufactured using the quantum dot composition obtained in Example 2. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 47%. In addition, the obtained wavelength conversion material was treated for 500 hours under conditions of 85° C. and 85% RH, and then the fluorescence emission efficiency was measured, resulting in an internal quantum efficiency of 46%.

### Example 15

A wavelength conversion material was manufactured using the quantum dot composition obtained in Example 3. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 45%. In addition, the obtained wavelength conversion material was treated for 500 hours under conditions of 85° C. and 85% RH, and then the fluorescence emission efficiency was measured, resulting in an internal quantum efficiency of 44%.

### Example 16

A wavelength conversion material was manufactured using the quantum dot composition obtained in Example 4. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 43%. In addition, the obtained wavelength conversion material was treated for 500 hours under conditions of 85° C. and 85% RH, and then the fluorescence emission efficiency was measured, resulting in an internal quantum efficiency of 41%.

### Example 17

A wavelength conversion material was manufactured using the quantum dot composition obtained in Example 5. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 98 μm. In addition, the internal quantum efficiency of the obtained wavelength conversion material was 33%. In addition, the obtained wavelength conversion material was treated for 500 hours under conditions of 85° C. and 85% RH, and then the fluorescence emission efficiency was measured, resulting in an internal quantum efficiency of 32%.

### Example 18

A wavelength conversion material was manufactured using the quantum dot composition obtained in Example 6. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 100 μm. In addition, the internal quantum efficiency of the obtained wavelength conversion material was 32%. In addition, the obtained wavelength conversion material was treated for 500 hours under conditions of 85° C. and 85% RH, and then the fluorescence emission efficiency was measured, resulting in an internal quantum efficiency of 31%.

### Example 19

A wavelength conversion material was manufactured using the quantum dot composition obtained in Example 7. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 47%. In addition, the obtained wavelength conversion material was treated for 500 hours under conditions of 85° C. and 85% RH, and then the fluorescence emission efficiency was measured, resulting in an internal quantum efficiency of 45%.

### Example 20

A wavelength conversion material was manufactured using the quantum dot composition obtained in Example 8. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 45%. In addition, the obtained wavelength conversion material was treated for 500 hours under conditions of 85° C. and 85% RH, and then the fluorescence emission efficiency was measured, resulting in an internal quantum efficiency of 43%.

### Example 21

A wavelength conversion material was manufactured using the quantum dot composition obtained in Example 9. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 98 μm. In addition, the internal quantum efficiency of the obtained wavelength conversion material was 46%. In addition, the obtained wavelength conversion material was treated for 500 hours under conditions of 85° C. and 85% RH, and then the fluorescence emission efficiency was measured, resulting in an internal quantum efficiency of 45%.

### Example 22

A wavelength conversion material was manufactured using the quantum dot composition obtained in Example 10. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 96 μm. In addition, the internal quantum efficiency of the obtained wavelength conversion material was 33%. In addition, the obtained wavelength conversion material was treated for 500 hours under conditions of 85° C. and 85% RH, and then the fluorescence emission efficiency was measured, resulting in an internal quantum efficiency of 31%.

### Example 23

A wavelength conversion material was manufactured using the quantum dot composition obtained in Example 11. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 32%. In addition, the obtained wavelength conversion material was treated for 500 hours under conditions of 85° C. and 85% RH, and then the fluorescence emission efficiency was measured, resulting in an internal quantum efficiency of 30%.

### Example 24

A wavelength conversion material was manufactured using the quantum dot composition obtained in Example 12. 2.5 g of a 20 wt % toluene solution of the quantum dot composition was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 33%. In addition, the obtained wavelength conversion material was treated for 500 hours under conditions of 85° C. and 85% RH, and then the fluorescence emission efficiency was measured, resulting in an internal quantum efficiency of 30%.

### Comparative Example 1

A wavelength conversion material was manufactured using the quantum dot obtained in Manufacturing Example 1. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 96 μm. In addition, the internal quantum efficiency of the obtained wavelength conversion material was 48%. In addition, the obtained wavelength conversion material was treated for 500 hours under conditions of 85° C. and 85% RH, and then the fluorescence emission efficiency was measured, resulting in an internal quantum efficiency of 27%.

### Comparative Example 2

A wavelength conversion material was manufactured using the quantum dot obtained in Manufacturing Example 2. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 98 μm. In addition, the internal quantum efficiency of the obtained wavelength conversion material was 34%. In addition, the obtained wavelength conversion material was treated for 500 hours under conditions of 85° C. and 85% RH, and then the fluorescence emission efficiency was measured, resulting in an internal quantum efficiency of 20%.

### Comparative Example 3

A wavelength conversion material was manufactured using the oxide-coated quantum dot obtained in Manufacturing Example 3. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 97 μm. In addition, the internal quantum efficiency of the obtained wavelength conversion material was 44%. In addition, the obtained wavelength conversion material was treated for 500 hours under conditions of 85° C. and 85% RH, and then the fluorescence emission efficiency was measured, resulting in an internal quantum efficiency of 33%.

### Comparative Example 4

A wavelength conversion material was manufactured using the oxide-coated quantum dot obtained in Manufacturing Example 4. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 47%. In addition, the obtained wavelength conversion material was treated for 500 hours under conditions of 85° C. and 85% RH, and then the fluorescence emission efficiency was measured, resulting in an internal quantum efficiency of 36%.

### Comparative Example 5

A wavelength conversion material was manufactured using the oxide-coated quantum dot obtained in Manufacturing Example 5. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 97 μm. In addition, the internal quantum efficiency of the obtained wavelength conversion material was 46%. In addition, the obtained wavelength conversion material was treated for 500 hours under conditions of 85° C. and 85% RH, and then the fluorescence emission efficiency was measured, resulting in an internal quantum efficiency of 36%.

### Comparative Example 6

A wavelength conversion material was manufactured using the oxide-coated quantum dot obtained in Manufacturing Example 6. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 99 μm. In addition, the internal quantum efficiency of the obtained wavelength conversion material was 42%. In addition, The obtained wavelength conversion material was treated for 500 hours under conditions of 85° C. and 85% RH, and then the fluorescence emission efficiency was measured, resulting in an internal quantum efficiency of 34%.

### Comparative Example 7

A wavelength conversion material was prepared using the oxide-coated quantum dot obtained in Manufacturing Example 7. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 100 μm. In addition, the internal quantum efficiency of the obtained wavelength conversion material was 33%. In addition, the obtained wavelength conversion material was treated for 500 hours under conditions of 85° C. and 85% RH, and then the fluorescence emission efficiency was measured, resulting in an internal quantum efficiency of 23%.

### Comparative Example 8

A wavelength conversion material was manufactured using the oxide-coated quantum dot obtained in Manufacturing Example 8. 2.5 g of a 20 wt % toluene solution of the quantum dot was mixed with 5.0 g of acrylic resin (ACRYDIC BL-616-BA, manufactured by DIC Corporation), and the solvent was removed under reduced pressure while the mixture was stirred and heated at 60° C.

The mixture was then vacuum-degassed and applied to a 50 μm-thick polyethylene terephthalate (PET) film, and a resin composition layer was formed using a bar coater. A PET film was further laminated onto this resin composition layer. This film was heated at 60° C. for 2 hours and then at 150° C. for 4 hours to cure the resin composition layer, thereby manufacturing a wavelength conversion material.

The thickness of the obtained wavelength conversion material was 98 μm. In addition, the internal quantum efficiency of the obtained wavelength conversion material was 32%. In addition, the obtained wavelength conversion material was treated for 500 hours under conditions of 85° C. and 85% RH, and then the fluorescence emission efficiency was measured, resulting in an internal quantum efficiency of 24%.

These results are shown in Table 2.

TABLE 2

| | | Wavelength conversion material | |
|---|---|---|---|
| | | Internal quantum | Internal quantum |
| | | efficiency before | efficiency after |
| | Quantum dot or quantum | treatment of 85 °C | treatment of 85 °C |
| | dot composition | and 85% RH (%) | and 85% RH (%) |
| Example 13 | Example 1: | 44 | 41 |
| | InP/ZnSe/ZnS/SiO2/HDPA | | |
| Example 14 | Example 2: | 47 | 46 |
| | InP/ZnSe/ZnS/Al2O3/HDPA | | |
| Example 15 | Example 3: | 45 | 44 |
| | InP/ZnSe/ZnS/ZrO2/HDPA | | |
| Example 16 | Example 4: | 43 | 41 |
| | InP/ZnSe/ZnS/TiO2/HDPA | | |
| Example 17 | Example 5: | 33 | 32 |
| | AgInS2/ZnS/Al2O3/HDPA | | |
| Example 18 | Example 6: | 32 | 31 |
| | AgInS2/ZnS/ZrO2/HDPA | | |
| Example 19 | Example 7: | 47 | 45 |
| | InP/ZnSe/ZnS/Al2O3/DDPA | | |
| Example 20 | Example 8: | 45 | 43 |
| | InP/ZnSe/ZnS/Al2O3/BBPA | | |
| Example 21 | Example 9: | 46 | 45 |
| | InP/ZnSe/ZnS/Al2O3/PhPA | | |
| Example 22 | Example 10: | 33 | 31 |
| | AgInS2/ZnS/Al2O3/DDPA | | |
| Example 23 | Example 11: | 32 | 30 |
| | AgInS2/ZnS/Al2O3/BBPA | | |
| Example 24 | Example 12: | 33 | 30 |
| | AgInS2/ZnS/Al2O3/PhPA | | |
| Comparative | Manufacturing Example 1: | 48 | 27 |
| Example 1 | InP/ZnSe/ZnS | | |
| Comparative | Manufacturing Example 2: | 34 | 20 |
| Example 2 | AgInS2/ZnS | | |
| Comparative | Manufacturing Example 3: | 44 | 33 |
| Example 3 | InP/ZnSe/ZnS/SiO2 | | |
| Comparative | Manufacturing Example 4: | 47 | 36 |
| Example 4 | InP/ZnSe/ZnS/Al2O3 | | |
| Comparative | Manufacturing Example 5: | 46 | 36 |
| Example 5 | InP/ZnSe/ZnS/ZrO2 | | |
| Comparative | Manufacturing Example 6: | 42 | 34 |
| Example 6 | InP/ZnSe/ZnS/TiO2 | | |
| Comparative | Manufacturing Example 7: | 33 | 23 |
| Example 7 | AgInS2/ZnS/Al2O3 | | |
| Comparative | Manufacturing Example 8: | 32 | 24 |
| Example 8 | AgInS2/ZnS/ZrO2 | | |

The internal quantum efficiency values after 500 hours of treatment under conditions of 85° C. and 85% RH were compared for the wavelength conversion materials manufactured in Example 13 with Comparative Examples 1 and 3, Examples 14 and 19 to 21 with Comparative Examples 1 and 4, Example 15 with Comparative Examples 1 and 5, Example 16 with Comparative Examples 1 and 6, Examples 17 and 22 to 24 with Comparative Examples 2 and 7, and Example 18 with Comparative Examples 2 and 8, respectively, and as a result, it has been confirmed that the wavelength conversion materials manufactured in Examples 13 to 24 using the quantum dot composition of the present invention, which had a metal oxide layer formed thereon and were surface-modified with a phosphonic acid derivative, exhibited higher internal quantum efficiency values than the quantum dots and the quantum dots on which only a metal oxide layer was formed.

As described above, it has been confirmed that the quantum dot composition, the resin composition using the quantum dot composition, and the wavelength conversion material obtained by curing the same, manufactured in the present invention are highly reliable, preventing reduction in the fluorescence emission efficiency under high-temperature and high-humidity conditions, despite using low-toxicity quantum dots.

The present description includes the following embodiments.
[1]: A quantum dot composition comprising a quantum dot that emits fluorescence by excitation light, the quantum dot comprising a semiconductor nanoparticle core and a semiconductor nanoparticle shell that do not contain Cd and Pb, wherein a surface of the quantum dot is coated with a metal oxide, and the surface of the quantum dot or a surface of the metal oxide is modified with a phosphonic acid derivative.
[2]: The quantum dot composition according to the above [1], wherein the quantum dot comprises the semiconductor nanoparticle core and a single or a plurality of the semiconductor nanoparticle shells covering the semiconductor nanoparticle core.
[3]: The quantum dot composition according to the above [1] or [2], wherein the semiconductor nanoparticle core comprises one or more selected from ZnS, ZnSe, ZnTe, AlN, AlP, AlAs, AlSb, GaN, GaP, GaAs, GaSb, InN, InP, InAs, InSb, AgGaS₂, AgInS₂, AgGaSe₂, AgInSe₂, CuGaS₂, CuGaSe₂, CuInS₂, CuInSe₂, ZnSiP₂, and ZnGeP₂, or a mixed crystal thereof.
[4]: The quantum dot composition according to any of the above [1] to [3], wherein a surface of the semiconductor nanoparticle core is passivated with one or more compounds selected from GaCl₃, GaI₃, GaBr₃, ZnCl₂, ZnBr₂, ZnI₂, InCl₃, InBr₃, InI₃, AgCl, AgBr, AgI, KCl, KBr, KI, NaCl, NaBr, NaI, MgCl₂, MgBr₂, MgI₂, CaCl₂, CaBr₂, CaI₂, MnCl₂, MnBr₂, MnI₂, FeCl₂, FeBr₂, FeI₂, CuCl₂, CuBr₂, CuI₂, ZrCl₄, ZrBr₄, ZrI₄, Z GeCl₄, GeBr₄, and GeI₄.
[5]: The quantum dot composition according to any of the above [1] to [4], wherein the semiconductor nanoparticle shell comprises one or more selected from ZnS, ZnSe, ZnTe, AlN, AlP, AlAs, AlSb, GaN, GaP, GaAs, GaSb, InN, InP, InAs, and InSb, or a mixed crystal thereof.
[6]: The quantum dot composition according to any of the above [1] to [5], wherein the metal oxide is at least one compound selected from TiO₂, ZnO, Al₂O₃, SiO₂, ZrO₂, Fe₂O₃, MgO, Y₂O₃, HfO₂, CeO₂, In₂O₃, SnO₂, WO₃, CrO₃, Ta₂O₃, BaTiO₃, V₂O₅, NiO, NbO, Cu₂O, CuO, and MoO₃.
[7]: The quantum dot composition according to any of the above [1] to [6], wherein the phosphonic acid derivative is represented by the following formula (I):

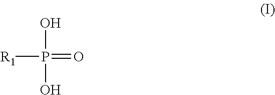

wherein R₁ is a monovalent organic group having one or more carbon atoms.
[8]: The quantum dot composition according to the above [7], wherein the phosphonic acid derivative is one or more selected from 3-phenyl-2-propynylphosphonic acid, tenofovir, 2-phosphonobutane-1,2,4-tricarboxylic acid, 4-phosphonobenzoic acid, vinylphosphonic acid, n-octylphosphonic acid, (3-bromopropyl)phosphonic acid, (4-bromobutyl)phosphonic acid, (2-bromoethyl)phosphonic acid, (4-bromophenyl)phosphonic acid, 3-phosphonopropionic acid, (4-hydroxyphenyl)phosphonic acid, hexylphosphonic acid, 4-phosphonobutyric acid, propylphosphonic acid, (4-aminobenzyl)phosphonic acid, (4-aminophenyl)phosphonic acid, 3-phosphonobenzoic acid, methylphosphonic acid, nonylphosphonic acid, benzhydrylphosphonic acid, octadecylphosphonic acid, (aminomethyl)phosphonic acid, (2-phenylethyl)phosphonic acid, ethylphosphonic acid, butylphosphonic acid, decylphosphonic acid, dodecylphosphonic acid, (2-chloroethyl)phosphonic acid, 4-methoxyphenylphosphonic acid, hexadecylphosphonic acid, (4-hydroxybenzyl)phosphonic acid, phenylphosphonic acid, (1H,1H,2H,2H-heptadecafluorodecyl)phosphonic acid, tetradecylphosphonic acid, (1-aminoethyl)phosphonic acid, undecylphosphonic acid, heptylphosphonic acid, 10-carboxydecylphosphonic acid, 11-aminoundecylphosphonic acid hydrobromide, 11-hydroxyundecylphosphonic acid, 1H,1H,2H,2H-perfluoro-n-hexylphosphonic acid, 1H,1H,2H,2H-perfluorooctylphosphonic acid, 1H,1H,2H,2H-perfluoro-n-decylphosphonic acid, 11-{2-[2-(2-methoxyethoxy)ethoxy]ethoxy}undecylphosphonic acid, 12-mercaptodecylphosphonic acid, and [11-(acryloyloxy)undecyl]phosphonic acid.
[9]: The quantum dot composition according to any of the above [1] to [6], wherein the phosphonic acid derivative is represented by the following formula (II):

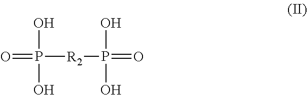

wherein R₂ is a divalent organic group having one or more carbon atoms.
[10]: The quantum dot composition according to the above [9], wherein the phosphonic acid derivative is one or more selected from m-xylylenediphosphonic acid, 0-xylylenediphosphonic acid, methylenediphosphonic acid, alendronic acid, 1,4-butylenediphosphonic acid, glycine-N, N-bis(methylenephosphonic acid), p-xylylenediphosphonic acid, zoledronic acid, 1,3-propylenediphosphonic acid, 1,5-pentylenediphosphonic acid, 1,4-phenylenediphosphonic acid, 1,2-ethylenediphosphonic acid, 1,6-hexylenediphosphonic acid, minodronate, and 1-hydroxyethane-1,1-diphosphonic acid.
[11]: The quantum dot composition according to any of the above [1] to [6], wherein the phosphonic acid derivative is represented by the following formula (III):

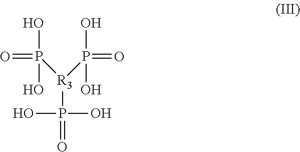

wherein R₃ is a trivalent organic group having one or more carbon atoms.
[12]: The quantum dot composition according to the above [11], wherein the phosphonic acid derivative is nitrilotris(methylenephosphonic acid).
[13]: The quantum dot composition according to any of the above [1] to [6], wherein the phosphonic acid derivative is represented by the following formula (IV):

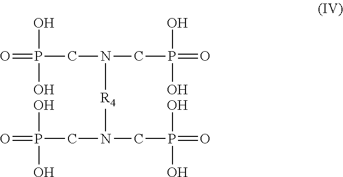

wherein R₄ is a divalent organic group having one or more carbon atoms.
[14]: The quantum dot composition according to the above [13], wherein the phosphonic acid derivative is N,N,N′,N′-ethylenediaminetetrakis(methylenephosphonic acid).
[15]: The quantum dot composition according to the above [7], wherein the R₁ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.
[16]: The quantum dot composition according to the above [9], wherein the R₂ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.
[17]: The quantum dot composition according to the above [11], wherein the R₃ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.
[18]: The quantum dot composition according to the above [13], wherein the Ra comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.
[19]: A resin composition comprising the quantum dot composition according to any of the above [1] to dispersed in a resin.
[20]: The resin composition according to the above [19], wherein the resin is at least one selected from an epoxy resin, an acrylic resin, a fluororesin, a silicone resin, a carbonate resin, and a glass resin.
[21]: A wavelength conversion material comprising a cured product of the resin composition according to the above [20].

Note that the present invention is not limited to the above-described embodiments. The above-described embodiments are merely illustrative, and any configuration that has substantially the same structure as the technical concept described in the claims of the present invention and achieves similar effects is within the technical scope of the present invention.

1.-21. (canceled)

22. A quantum dot composition comprising a quantum dot that emits fluorescence by excitation light, the quantum dot comprising a semiconductor nanoparticle core and a semiconductor nanoparticle shell that do not contain Cd and Pb, wherein a surface of the quantum dot is coated with a metal oxide, and the surface of the quantum dot or a surface of the metal oxide is modified with a phosphonic acid derivative.

23. The quantum dot composition according to claim 22, wherein the quantum dot comprises the semiconductor nanoparticle core and a single or a plurality of the semiconductor nanoparticle shells covering the semiconductor nanoparticle core.

24. The quantum dot composition according to claim 22, wherein the semiconductor nanoparticle core comprises one or more selected from ZnS, ZnSe, ZnTe, AlN, AIP, AlAs, AlSb, GaN, GaP, GaAs, GaSb, InN, InP, InAs, InSb, AgGaS₂, AgInS₂, AgGaSe₂, AgInSe₂, CuGaS₂, CuGaSe₂, CuInS₂, CuInSe₂, ZnSiP₂, and ZnGeP₂, or a mixed crystal thereof.

25. The quantum dot composition according to claim 22, wherein a surface of the semiconductor nanoparticle core is passivated with one or more compounds selected from GaCl₃, GaI₃, GaBr₃, ZnCl₂, ZnBr₂, ZnI₂, InCl₃, InBr₃, InI₃, AgCl, AgBr, AgI, KCl, KBr, KI, NaCl, NaBr, NaI, MgCl₂, MgBr₂, MgI₂, CaCl₂), CaBr₂, CaI₂, MnCl₂, MnBr₂, MnI₂, FeCl₂, FeBr₂, FeI₂, CuCl₂, CuBr₂, CuI₂, ZrCl₄, ZrBr₄, ZrI₄, GeCl₄, GeBr₄, and GeI₄.

26. The quantum dot composition according to claim 22, wherein the semiconductor nanoparticle shell comprises one or more selected from ZnS, ZnSe, ZnTe, AlN, AIP, AlAs, AlSb, GaN, GaP, GaAs, GaSb, InN, InP, InAs, and InSb, or a mixed crystal thereof.

27. The quantum dot composition according to claim 22, wherein the metal oxide is at least one compound selected from TiO₂, ZnO, Al₂O₃, SiO₂, ZrO₂, Fe₂O₃, MgO, Y₂O₃, HfO₂, CeO₂, In₂O₃, SnO₂, WO₃, CrO₃, Ta₂O₃, BaTiO₃, V₂O₅, NiO, NbO, Cu₂O, CuO, and MoO₃.

28. The quantum dot composition according to claim 22, wherein the phosphonic acid derivative is represented by the following formula (I): 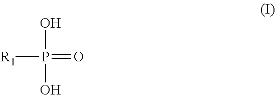
wherein R₁ is a monovalent organic group having one or more carbon atoms.

29. The quantum dot composition according to claim 28, wherein the phosphonic acid derivative is one or more selected from 3-phenyl-2-propynylphosphonic acid, tenofovir, 2-phosphonobutane-1,2,4-tricarboxylic acid, 4-phosphonobenzoic acid, vinylphosphonic acid, n-octylphosphonic acid, (3-bromopropyl)phosphonic acid, (4-bromobutyl)phosphonic acid, (2-bromoethyl)phosphonic acid, (4-bromophenyl)phosphonic acid, 3-phosphonopropionic acid, (4-hydroxyphenyl)phosphonic acid, hexylphosphonic acid, 4-phosphonobutyric acid, propylphosphonic acid, (4-aminobenzyl)phosphonic acid, (4-aminophenyl)phosphonic acid, 3-phosphonobenzoic acid, methylphosphonic acid, nonylphosphonic acid, benzhydrylphosphonic acid, octadecylphosphonic acid, (aminomethyl)phosphonic acid, (2-phenylethyl)phosphonic acid, ethylphosphonic acid, butylphosphonic acid, decylphosphonic acid, dodecylphosphonic acid, (2-chloroethyl)phosphonic acid, 4-methoxyphenylphosphonic acid, hexadecylphosphonic acid, (4-hydroxybenzyl)phosphonic acid, phenylphosphonic acid, (1H,1H,2H,2H-heptadecafluorodecyl)phosphonic acid, tetradecylphosphonic acid, (1-aminoethyl)phosphonic acid, undecylphosphonic acid, heptylphosphonic acid, 10-carboxydecylphosphonic acid, 11-aminoundecylphosphonic acid hydrobromide, 11-hydroxyundecylphosphonic acid, 1H,1H,2H,2H-perfluoro-n-hexylphosphonic acid, 1H,1H,2H,2H-perfluorooctylphosphonic acid, 1H,1H,2H,2H-perfluoro-n-decylphosphonic acid, 11-{2-[2-(2-methoxyethoxy)ethoxy]ethoxy}undecylphosphonic acid, 12-mercaptodecylphosphonic acid, and [11-(acryloyloxy)undecyl]phosphonic acid.

30. The quantum dot composition according to claim 22, wherein the phosphonic acid derivative is represented by the following formula (II): 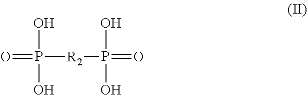
wherein R₂ is a divalent organic group having one or more carbon atoms.

31. The quantum dot composition according to claim 30, wherein the phosphonic acid derivative is one or more selected from m-xylylenediphosphonic acid, o-xylylenediphosphonic acid, methylenediphosphonic acid, alendronic acid, 1,4-butylenediphosphonic acid, glycine-N,N-bis(methylenephosphonic acid), p-xylylenediphosphonic acid, zoledronic acid, 1,3-propylenediphosphonic acid, 1,5-pentylenediphosphonic acid, 1,4-phenylenediphosphonic acid, 1,2-ethylenediphosphonic acid, 1,6-hexylenediphosphonic acid, minodronate, and 1-hydroxyethane-1,1-diphosphonic acid.

32. The quantum dot composition according to claim 22, wherein the phosphonic acid derivative is represented by the following formula (III): 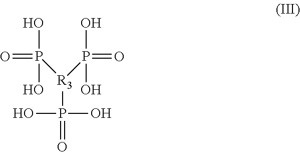
wherein R₃ is a trivalent organic group having one or more carbon atoms.

33. The quantum dot composition according to claim 32, wherein the phosphonic acid derivative is nitrilotris(methylenephosphonic acid).

34. The quantum dot composition according to claim 22, wherein the phosphonic acid derivative is represented by the following formula (IV): 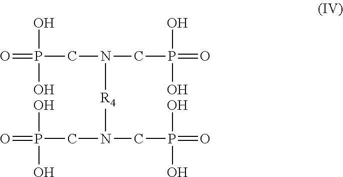
wherein R₄ is a divalent organic group having one or more carbon atoms.

35. The quantum dot composition according to claim 34, wherein the phosphonic acid derivative is N,N,N′,N′-ethylenediaminetetrakis(methylenephosphonic acid).

36. The quantum dot composition according to claim 28, wherein the R₁ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

37. The quantum dot composition according to claim 30, wherein the R₂ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

38. The quantum dot composition according to claim 32, wherein the R₃ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

39. The quantum dot composition according to claim 34, wherein the R₄ comprises at least one of a linear or branched alkyl group having one or more carbon atoms, a linear or branched alkylene group having one or more carbon atoms, an amino group, a carboxylic acid group, an ethoxy group, a bromo group, a chloro group, a phenol group, a perfluoroalkyl group, a hydroxy group, a phenyl group, a thiol group, an acryloyl group, and an oligoethylene glycol group.

40. A resin composition comprising the quantum dot composition according to claim 22 dispersed in a resin.

41. The resin composition according to claim 40, wherein the resin is at least one selected from an epoxy resin, an acrylic resin, a fluororesin, a silicone resin, a carbonate resin, and a glass resin.

42. A wavelength conversion material comprising a cured product of the resin composition according to claim 41.
